(19) United States
(12) Patent Application Publication
(10) Pub. No.: US 2024/0312861 A1
(43) Pub. Date: Sep. 19, 2024

(54) THREE-DIMENSIONAL PACKAGE STRUCTURE AND METHOD FOR FORMING SAME

(71) Applicant: JCET Group Co. Ltd., Wuxi (CN)

(72) Inventors: Chen XU, Wuxi (CN); JianYong WU, Wuxi (CN); Shuo LIU, Wuxi (CN)

(73) Assignee: JCET Group Co. Ltd., Wuxi, JS (CN)

(21) Appl. No.: 18/607,298

(22) Filed: Mar. 15, 2024

(30) Foreign Application Priority Data
Mar. 17, 2023 (CN) 202310264432.2

(51) Int. Cl. H01L 23/367; H01L 23/00; H01L 23/31; H01L 25/10

(52) U.S. Cl. CPC H01L 23/367; H01L 23/3128; H01L 24/16; H01L 24/32; H01L 24/73; H01L 24/81; H01L 24/83; H01L 25/105; H01L 2224/16225; H01L 2224/32245; H01L 2224/73253; H01L 2224/81; H01L 2224/83; H01L 2224/92225

(57) ABSTRACT

Disclosed are a three-dimensional package structure and a method for forming the same. The method includes: flip-mounting the first die onto the first substrate; mounting the heat conductive plate onto the first substrate, such that bottom portions of the two vertical plates of the heat conductive plate are attached onto a surface of the first substrate and the lateral plate is attached onto a surface, away from the first substrate, of the first die; mounting the second substrate over the first substrate, such that top portions of the two vertical plates of the heat conductive plate are respectively embedded into the two openings; filling up a space between the first substrate and the second substrate with a molding layer; flip-mounting the second die onto a surface of the second substrate; and mounting the heat sink, such that the heat sink encircles an outer surface of the second die.

### CROSS-REFERENCE TO RELATED APPLICATIONS

This application is based upon and claims priority to Chinese Patent Application No. 202310264432.2, filed on Mar. 17, 2023, the entire content of which is incorporated herein by reference for all purposes.

### TECHNICAL FIELD

The present disclosure relates to the technical field of semiconductor packaging, and in particular, relates to a three-dimensional package structure and a method for forming the same.

### BACKGROUND

Conventionally, system-in-package (SiP), such as the package-in-package (PiP), package-on-package (POP), has been used to integrate dies together. However, with applications such as smartphones and AIoT, not only higher performance but also small volume and low power consumption are required. In such a case, more dies need be stacked to reduce the volume. Therefore, the current packaging technique has been developed towards three-dimensional (3D) packaging in addition to the original SiP.

In the 3D packaging, due to stacking of a plurality of layers of dies, heat dissipation of the dies, particularly heat dissipation of underlying dies is an urgent problem to be addressed.

### SUMMARY

In view of the above, embodiments of the present disclosure provide a method for forming a three-dimensional package structure.

The method includes:
providing a first substrate, a second substrate, at least one first die, a second die, a heat conductive plate, and a heat sink, wherein the heat conductive plate comprises two vertical plates and a lateral plate secured to middle positions of the two vertical plates, and two openings running through the second substrate are defined in the second substrate;
flip-mounting the at least one first die onto the first substrate;
mounting the heat conductive plate onto the first substrate, such that bottom portions of the two vertical plates of the heat conductive plate are attached onto a surface of the first substrate and the lateral plate is attached onto a surface, away from the first substrate, of the at least one first die;
mounting the second substrate over the first substrate, such that top portions of the two vertical plates of the heat conductive plate are respectively embedded into the two openings;
filling up a space between the first substrate and the second substrate with a molding layer, wherein the molding layer wraps the at least one first die and the lateral plate;
flip-mounting the second die onto a surface, away from the molding layer, of the second substrate; and
mounting the heat sink onto the surface, away from the molding layer, of the second substrate, such that the heat sink encircles an outer surface of the second die.

In some embodiments, the method further includes: providing an interposer structure, wherein the interposer structure is positioned between the first substrate and the second substrate and positioned on two sides of the lateral plate of the heat conductive plate, and the interposer structure is configured to be electrically connected to the first substrate and the second substrate.

In some embodiments, a first wiring is arranged in the first substrate, and a second wiring is arranged in the second substrate, wherein the at least one first die is electrically connected to the first wiring, the second die is electrically connected to the second wiring, the interposer structure is electrically connected to the first wiring and the second wiring, and the interposer structure includes an interposer plate or a columnar conductive structure.

In some embodiments, when a plurality of first dies are arranged, the plurality of first dies are dies having the same function or different functions and are flip-mounted onto the first substrate, the bottom portions of the two vertical plates of the heat conductive plate are attached onto the surface of the first substrate outside the plurality of first dies, and the lateral plate is attached onto the surface, away from the first substrate, of each of the plurality of first dies.

In some embodiments, heights of the plurality of first dies flip-mounted onto the first substrate are equal or different.

In some embodiments, when heights of the plurality of first dies flip-mounted onto the first substrate are equal, the lateral plate of the heat conductive plate is a flat plate.

In some embodiments, when the heights of the plurality of first dies flip-mounted onto the first substrate are different, an upper surface of the lateral plate of the heat conductive plate is a flat surface, and a raised portion or a recessed portion is defined on or in a lower surface of the lateral plate, wherein the recessed portion in the lower surface of the lateral plate is attached onto a surface, away from the first substrate, of a first die with a larger height, or the raised portion in the lower surface of the lateral plate is attached onto a surface, away from the first substrate, of a first die with a smaller height.

In some embodiments, the bottom portions of the two vertical plates of the heat conductive plate are attached onto the surface of the first substrate by an adhesive, the lateral plate is attached onto the surface, away from the first substrate, of the first die by a thermal conductive adhesive, the heat sink is attached onto the second die by a thermal conductive adhesive, and the heat sink is adhered onto the second substrate by a thermal conductive adhesive and/or an adhesive.

In some embodiments, part of the heat sink covers the openings in the second substrate, and the heat sink covering the openings in the second substrate is attached by a thermal conductive adhesive.

Embodiments of the present disclosure provide a three-dimensional package structure. The three-dimensional package structure includes:
at least one layer of first package, a second substrate, a second die, and a heat sink, wherein two openings running through the second substrate are defined in the second substrate; wherein
the at least one layer of first package comprises a first substrate, at least one first die, a heat conductive plate, and a molding layer, wherein the heat conductive plate comprises two vertical plates and a lateral plate secured to middle positions of the two vertical plates, and the first die is flip-mounted onto a surface of the first substrate; the heat conductive plate is mounted onto the surface of the first substrate, such that bottom portions of the two vertical plates of the heat conductive plate are attached onto the surface of the first substrate and the lateral plate is attached onto a surface, away from the first substrate, of the first die; and the molding layer wraps the first die and the lateral plate, and exposes top surfaces of the two vertical plates;
the second substrate is positioned on the first package, and top portions of the two vertical plates of the heat conductive plate are respectively embedded into the two openings;
the second die is positioned on a surface, away from the molding layer, of the second substrate; and
the heat sink is positioned on the surface, away from the molding layer, of the second substrate, and the heat sink encircles an outer surface of the second die.

In some embodiments, the method further includes: providing an interposer structure, wherein the interposer structure is positioned between the first substrate and the second substrate and positioned on two sides of the lateral plate of the heat conductive plate, and the interposer structure is configured to be electrically connected to the first substrate and the second substrate.

In some embodiments, a first wiring is arranged in the first substrate, and a second wiring is arranged in the second substrate, wherein the first die is electrically connected to the first wiring, the second die is electrically connected to the second wiring, the interposer structure is electrically connected to the first wiring and the second wiring, and the interposer structure includes an interposer plate or a columnar conductive structure.

In some embodiments, when a plurality of first dies are arranged, the plurality of first dies are dies having the same function or different functions and are flip-mounted onto the first substrate, the bottom portions of the two vertical plates of the heat conductive plate are attached onto the surface of the first substrate outside the plurality of first dies, and the lateral plate is attached onto the surface, away from the first substrate, of each of the plurality of first dies.

In some embodiments, heights of the plurality of first dies flip-mounted onto the first substrate are equal or different.

In some embodiments, when heights of the plurality of first dies flip-mounted onto the first substrate are equal, the lateral plate of the heat conductive plate is a flat plate.

In some embodiments, when the heights of the plurality of first dies flip-mounted onto the first substrate are different, an upper surface of the lateral plate of the heat conductive plate is a flat surface, and a raised portion or a recessed portion is defined on or in a lower surface of the lateral plate, wherein the recessed portion in the lower surface of the lateral plate is attached onto a surface, away from the first substrate, of a first die with a larger height, or the raised portion in the lower surface of the lateral plate is attached onto a surface, away from the first substrate, of a first die with a smaller height.

In some embodiments, the bottom portions of the two vertical plates of the heat conductive plate are attached onto the surface of the first substrate by an adhesive, the lateral plate is attached onto the surface, away from the first substrate, of the at least one first die by a thermal conductive adhesive, the heat sink is attached onto the second die by a thermal conductive adhesive, and the heat sink is adhered onto the second substrate by a thermal conductive adhesive and/or an adhesive.

In some embodiments, part of the heat sink covers the openings in the second substrate, and the heat sink covering the openings in the second substrate is attached by a thermal conductive adhesive.

In some embodiments, when a plurality of layers of the first package are arranged, the plurality of layers of the first package are stacked along a vertical direction, and the second substrate is mounted over the first substrate in the first package in an uppermost layer; and the first substrates in upper and lower layers are electrically connected by a second interposer structure.

In the method for forming the three-dimensional package structure according to the embodiments of the present disclosure, at least one first die is flip-mounted onto the first substrate; the heat conductive plate is mounted onto the first substrate, such that bottom portions of the two vertical plates of the heat conductive plate are attached onto a surface of the first substrate and the lateral plate is attached onto a surface, away from the first substrate, of the first die; the second substrate is mounted over the first substrate, such that top portions of the two vertical plates of the heat conductive plate are respectively embedded into the two openings; a space between the first substrate and the second substrate is filled up with a molding layer, wherein the molding layer wraps the at least one first die and the lateral plate; the second die is flip-mounted onto a surface, away from the molding layer, of the second substrate; and the heat sink is mounted onto the surface, away from the molding layer, of the second substrate, such that the heat sink encircles an outer surface of the second die. The heat conductive plate includes the two vertical plates and the lateral plate secured to the middle positions of the two vertical plates. The heat conductive plate is conveniently secured by mounting onto the first substrate, such that the bottom portions of the two vertical plates of the heat conductive plate are attached onto the surface of the first substrate, and the lateral plate is attached onto the surface, away from the first substrate, of the first die. In this way, the lateral plate may absorb heat produced by the at least one first die and transfers the heat to the two vertical plates. In addition to dissipating part of the heat, the two vertical plates may also transfer part of the heat upwards to the heat sink subsequently formed on the second substrate, such that the heat produced by the at least one first die that are packaged at the bottom is efficiently and quickly dissipated. In this way, the performance of the at least one first die is improved, and the at least one first die is prevented from damages. Through the openings in the second substrate, the heat in the heat conductive plate is more easily transferred upwards from the vertical plates to the heat sink, and the second substrate does not block transfer of the heat.

### BRIEF DESCRIPTION OF THE DRAWINGS

FIG. 1 is a top view of a first substrate in a process of forming a three-dimensional package structure according to some embodiments of the present disclosure;

FIG. 2 is a schematic structural sectional view of FIG. 1 taken along cutting line AA1;

FIG. 3 is a schematic structural sectional view of FIG. 1 taken along cutting line BB1;

FIG. 4 is a top view of a second substrate in the process of forming the three-dimensional package structure according to some embodiments of the present disclosure;

FIG. 5 is a schematic structural sectional view of FIG. 4 taken along cutting line AA1;

FIG. 6 is a schematic structural sectional view of FIG. 4 taken along cutting line BB1;

FIG. 7 is a top view of a first die flip-mounted onto the first substrate in the process of forming the three-dimensional package structure;

FIG. 8 is a schematic structural sectional view of FIG. 10 taken along cutting line AA1;

FIG. 9 is a schematic structural sectional view of FIG. 7 taken along cutting line;

FIG. 10 is a top view of a heat conductive plate flip-mounted onto the first substrate in the process of forming the three-dimensional package structure according to some embodiments of the present disclosure;

FIG. 11 is a schematic structural sectional view of FIG. 10 taken along cutting line AA1;

FIG. 12 is a schematic structural sectional view of FIG. 10 taken along cutting line BB1;

FIG. 13 is a schematic structural sectional view of FIG. 10 taken along cutting line BB1 in a process of forming a three-dimensional package structure according to some other embodiments of the present disclosure;

FIG. 13 is a schematic structural sectional view of FIG. 10 taken along cutting line BB1 in a process of forming a three-dimensional package structure according to some other embodiments of the present disclosure;

FIG. 15 is a schematic structural sectional view of FIG. 10 taken along cutting line AA1 in a process of forming a three-dimensional package structure according to some other embodiments of the present disclosure;

FIG. 16 is a top view of the second substrate flip-mounted onto the first substrate in the process of forming the three-dimensional package structure according to some embodiments of the present disclosure;

FIG. 17 is a schematic structural sectional view of FIG. 16 along cutting line AA1;

FIG. 18 is a schematic structural sectional view of FIG. 16 along cutting line BB1;

FIG. 19 is a top view of a second die flip-mounted onto a surface, away from a molding layer, of the second substrate in the process of forming the three-dimensional package structure according to some embodiments of the present disclosure;

FIG. 20 is a schematic structural sectional view of FIG. 19 taken along cutting line AA1;

FIG. 21 is a schematic structural sectional view of FIG. 19 taken along cutting line BB1;

FIG. 22 is a top view of a heat conductive plate mounted onto the surface, away from the molding layer, of the second substrate in the process of forming the three-dimensional package structure according to some embodiments of the present disclosure;

FIG. 23 is a schematic structural sectional view of FIG. 22 taken along cutting line AA1;

FIG. 24 is a schematic structural sectional view of FIG. 22 taken along cutting line BB1;

FIGS. 25 to 26 are schematic views of a plurality of external bumps formed on a lower surface of the first substrate; and

FIGS. 27 to 28 are schematic views of a three-dimensional package structure according to some embodiments.

### DETAILED DESCRIPTION

The specific embodiments of the present disclosure are described in detail hereinafter with reference to the accompanying drawings. In the description of the embodiments of the present disclosure, for ease of illustration, the schematic structural views are not partially enlarged according to a typical scale, and the schematic views are given for exemplary purpose only, which do not limit the protection scope of the present invention. In addition, in practice, a three-dimension spatial size in terms of length, width, and depth needs to be included.

Some embodiments of the present disclosure provide a method for forming a three-dimensional package structure.

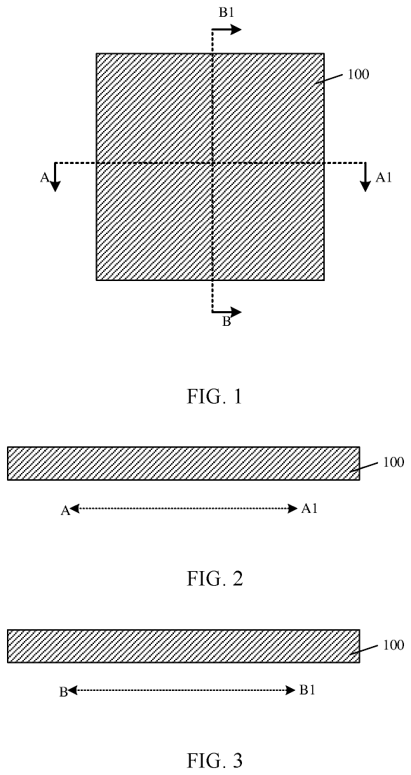

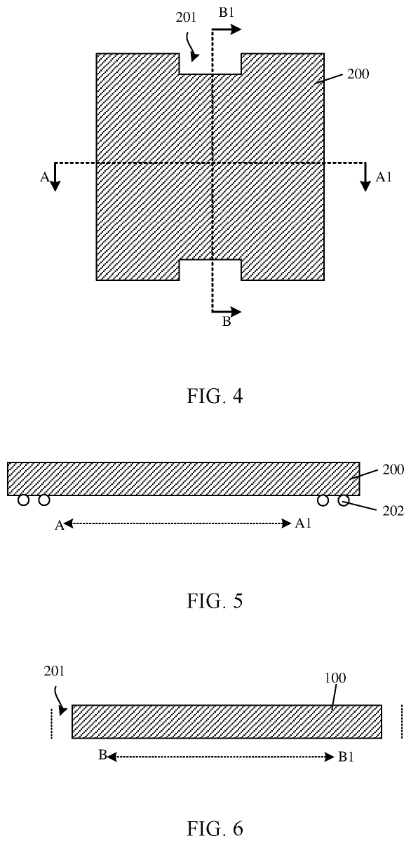

Referring to FIG. 1 to FIG. 6, FIG. 2 and FIG. 3 are respectively schematic structural sectional views of FIG. 1 taken along cutting line AA1 and cutting line BB1, and FIG. 5 and FIG. 6 are respectively schematic structural sectional views of FIG. 4 taken along cutting line AA1 and cutting line BB1, wherein a first substrate 100 (referring to FIG. 1 to FIG. 3) and a second substrate 200 (referring to FIG. 4 to FIG. 6) are provided. Two openings 201 running through the second substrate 200 are defined in the second substrate 200.

The first substrate 100 is a carrier of subsequent processes. A plurality of first electrical connection points (for example, exposed pads or metal connection ends, which are not illustrated in the drawings) are respectively arranged on opposite upper and lower surfaces of the first substrate 100. A first wiring (not illustrated in the drawings) is arranged in the first substrate 100. The first wiring is configured to be electrically connected to the plurality of first electrical connection points, and to be subsequently electrically connected to a first die and an interposer structure.

In some embodiments, the first substrate 100 may be one of a resin substrate, a ceramic substrate, a glass substrate, a silicon substrate, a metal substrate, a printed circuit board (PCB), or a flexible printed circuit (FPC). In some embodiments, the first substrate 100 may be a single-layer substrate or a multi-layer substrate.

A plurality of second electrical connection points (for example, exposed pads or metal connection ends, which are not illustrated in the drawings) are respectively arranged on opposite upper and lower surfaces of the second substrate 200. A second wiring (not illustrated in the drawings) is arranged in the first substrate 200. The second wiring is configured to be electrically connected to the plurality of second electrical connection points, and to be subsequently electrically connected to a second die and an interposer structure.

Two openings 201 running through the second substrate 200 are defined in the second substrate 200, and the openings 201 serve as a connection channel between a heat conductive plate and a heat sink, such that heat on the heat conductive plate is more easily transferred to the heat sink and dissipated. In some embodiments, the opening 201 may be an enclosed opening having four side walls, and upper and lower ends of the enclosed opening run through the upper and lower surfaces of the second substrate 200. In some embodiments, the openings 201 may also be semi-enclosed openings each having three side walls, and upper and lower ends of each of the semi-enclosed openings run through upper and lower surfaces of the second substrate 200.

In some embodiments, a plurality of bumps 202 are arranged on the lower surface of the second substrate 200, and the plurality of bumps 202 are connected to the corresponding second electrical connection points arranged on the lower surface of the second substrate 200. The first bumps 202 are made of tin or a tin alloy, wherein the tin alloy may be one or more of tin-silver, tin-lead, tin-silver-copper, tin-silver-zinc, tin-zinc, tin-bismuth-indium, tin-indium, tin-copper, tin-copper, tin-zinc-indium, or tin-silver-antimony.

The present disclosure further provides a first die (not illustrated in the drawings), a second die (not illustrated in the drawings), an interposer structure (not illustrated in the drawings), a heat conductive plate (not illustrated in the drawings), and a heat sink (not illustrated in the drawings). Hereinafter, these devices or structures are described in detail.

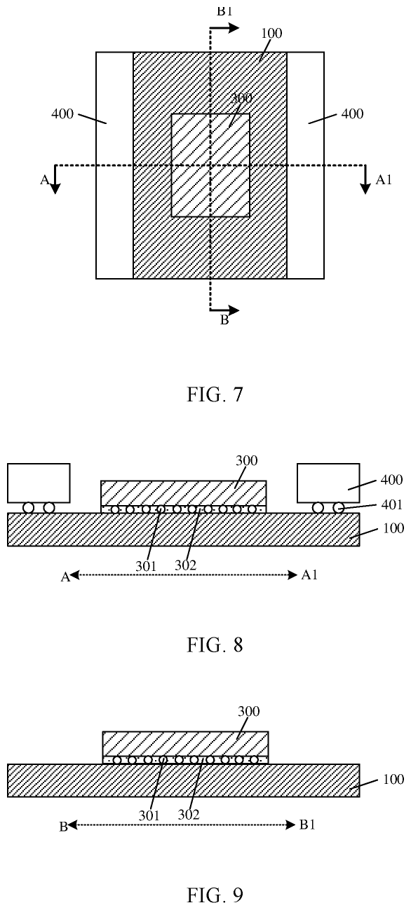

Referring to FIG. 7 to FIG. 9, FIG. 7 is based on FIG. 1, and FIG. 8 and FIG. 9 are respectively schematic structural sectional views of FIG. 7 taken along cutting line AA1 and cutting line BB1, wherein a first die 300 is provided. The first die 300 is flip-mounted onto the first substrate 100.

The first die 300 includes a back surface and an active surface opposite to the back surface. A plurality of second bumps 301 are arranged on the active surface, and the plurality of second bumps 301 are connected to an integrated circuit formed in the first die 300. In this embodiment, the active surface of the first die 300 is flip-mounted onto the first substrate 100 (or an upper surface of the first substrate 100), the second bumps 301 on the active surface of the first die 300 are soldered to part of the first electrical connection points on the first substrate 100.

The first die 300 is a die having a specific function. In a specific embodiment, the first die 300 includes, but is not limited to, a sensor die, a power source die, a signal processing die, a logic control die, a storage die, or a radio frequency die.

One or a plurality (equal to or more than 2) of first dies 300 may be arranged.

In some embodiments, when a plurality of first dies 300 are arranged, the plurality of first dies 300 are dies having the same function or different functions and are flip-mounted onto the first substrate 100. In some embodiments, when the plurality of first dies 300 are flip-mounted onto the first substrate 100, part of the first dies 300 may be flip-mounted onto the first substrate 100 along cutting line AA1, and part of the first dies 300 may be flip-mounted onto the first substrate 100 along cutting line BB1.

In some embodiments, heights of the plurality of first dies 300 flip-mounted onto the first substrate 100 are equal or different, that is, distances from the back surfaces of the plurality of first dies 300 to a surface of the first substrate 100 are different.

In some embodiments, the second bumps 301 may be solder balls. In some other embodiments, the second bumps 301 may include metal columns or solder balls on top surfaces of the metal columns. In some embodiments, the solder balls are made of Sn or an Sn alloy. The metal columns are made of aluminum, nickel, tungsten, platinum, copper, titanium, chromium, tantalum, tin alloy, gold, or silver

In some embodiments, after the first die 300 is flip-mounted onto the first substrate 100, a first underfill layer 302 is formed between the active surface of the first die 300 and the first substrate 100. The first underfill layer 302 is made of resin.

In some embodiments, an interposer structure 400 is soldered onto the first substrate 100 on both sides of the first die 300, and the interposer structure 400 is subsequently configured to be electrically connected to the first substrate 100 and the second substrate 200, such that the first die 300 on the first substrate 100 is electrically connected to the second die on the second substrate 200. A plurality of third bumps 401 are arranged on a surface, opposite to the first substrate 100, of the interposer structure 400, and the third bumps 401 and part of the first electrical connection points on the first substrate 100 are soldered together. In this embodiment, the interposer structure 400 is arranged on the first substrate 100 on both sides of the first die 300 along cutting line AA1, and a space for mounting the heat conductive plate is reserved on the first substrate 100 on both sides of the first die 300 long cutting line BB1.

In some embodiments, the interposer structure 400 includes an interposer plate or a columnar conductive structure. In this embodiment, the interposer structure 400 is an interposer plate. A third wiring is arranged in the interposer plate. A plurality of third bumps 401 are arranged on a lower surface of the interposer structure 400, and the third bumps 401 are electrically connected to the third wiring. In some other embodiments, when the interposer structure 400 is a columnar conductive structure, the columnar conductive structure is made of a metal, and the columnar conductive structure is directly soldered onto the first substrate 100.

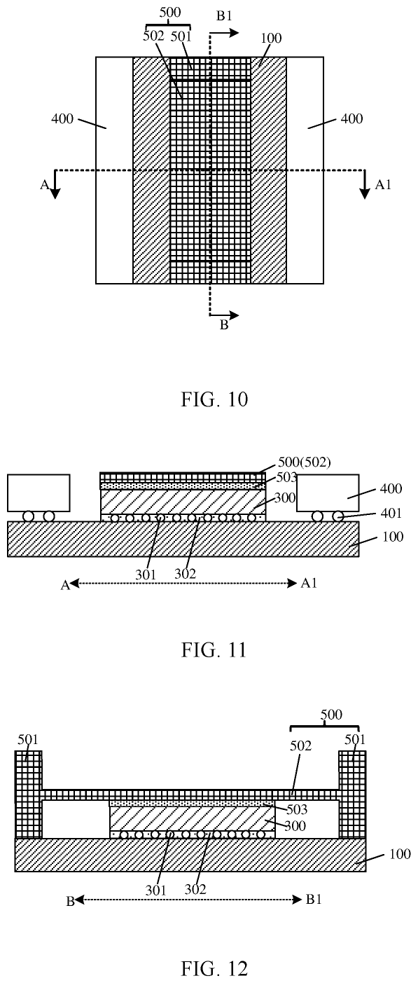

Referring to FIG. 10 to FIG. 12, FIG. 11 and FIG. 12 are respectively schematic structural sectional views of FIG. 10 taken along cutting line AA1 and cutting line BB1, wherein a heat conductive plate 500 is provided. The heat conductive plate 500 includes two vertical plates 501 and a lateral plate 502 secured to middle positions of the two vertical plates 501. The heat conductive plate 500 is mounted onto the first substrate 100, such that bottom portions of the two vertical plates 501 of the heat conductive plate 500 are attached onto the surface of the first substrate 100, and the lateral plate 502 is attached onto a surface, away from the first substrate 100, of the first die 300 (or a back surface of the first die 300).

The heat conductive plate 500 has an “H”-shaped cross section along cutting line BB1. The heat conductive plate 500 includes the two vertical plates 501 and the lateral plate 502 secured to the middle positions of the two vertical plates 501. The two vertical plates 501 and the lateral plate 502 are integrally formed, such that the mechanical stability and solidity are enhanced. In addition, the heat conductive plate 500 is conveniently secured by mounting onto the first substrate 100, such that the bottom portions of the two vertical plates 501 of the heat conductive plate 500 are attached onto the surface of the first substrate 100, and the lateral plate 502 is attached onto the surface, away from the first substrate 100, of the first die 300. In this way, the lateral plate 502 may absorb heat produced by the first die 300 and transfers the heat to the two vertical plates 501. In addition to dissipating part of the heat, the two vertical plates 501 may also transfer part of the heat upwards to the heat sink subsequently formed on the second substrate, such that the heat produced by the first die 300 that are packaged at the bottom is efficiently and quickly dissipated. In this way, the performance of the first die 300 is improved, and the first die 300 is prevented from damages.

The heat conductive plate 500 is made of a metal or an alloy. In some embodiments, the heat conductive plate 500 is made of copper, aluminum, or any other metals or alloys having good thermal conductivity.

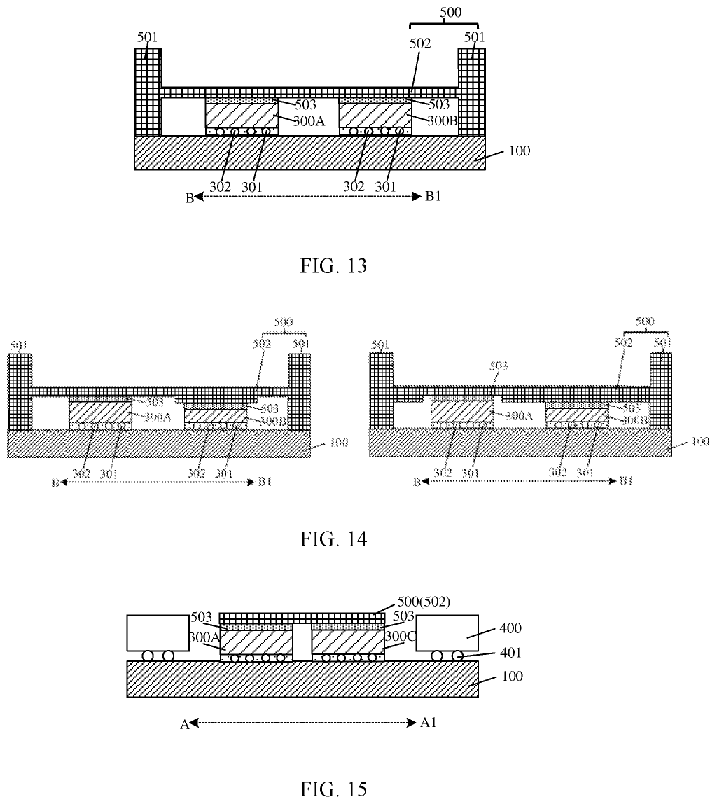

In this embodiment, only one first die 300 is flip-mounted onto the first substrate 100. In some other embodiments, referring to FIG. 13, when a plurality of first dies 300 (for example, 300A and 300B) are flip-mounted onto the first substrate 100, the bottom portions of the two vertical plates 501 of the heat conductive plate 500 are attached onto the surface of the first substrate 100 outside the plurality of first dies (300A and 300B), and the lateral plate 502 is attached onto the surface (a back surface of each of the first die 300A and 300B), away from the first substrate 100, of each of the plurality of first dies (300A and 300B), such that the heat produced by the plurality of first dies is dissipated by the heat conductive plate 500.

In some embodiments, still referring to FIG. 13, when heights of the plurality of first dies 300 (for example, the first dies 300A and 300B) flip-mounted onto the first substrate 100 are equal, the lateral plate 502 of the heat conductive plate 500 is a flat plate.

In some embodiments, referring to FIG. 14, a plurality of first dies 300 (for example, 300A and 300B) are flip-mounted onto the first substrate 100, and when heights of the plurality of first dies (300A and 300B) flip-mounted onto the first substrate 100 are different (for example, the height of the first die 300A on the left is greater than the height of the first die 300B on the right in the left part or right part in FIG. 14), an upper surface of the lateral plate 502 of the heat conductive plate 500 is a flat surface, and a raised portion (referring to the left part in FIG. 14) or a recessed portion (referring to the right part in FIG. 14) is formed on a lower surface of the lateral plate 502. The raised portion may have different heights depending on height differences of the first dies, and the recessed portion may have different heights depending on height difference. Description is given using the case where the two first dies (300A and 300B) the flip-mounted have different heights as an example, upon flip-mounting, the height of the first die 300A is greater than the height of the first die 300B, and correspondingly a raised portion (referring to the left part in FIG. 14) or a recessed portion (referring to the right part in FIG. 14) is formed on the lower surface of the lateral plate 502. During attaching of the lateral plate 502 in two different structures, referring to the left part in FIG. 14, the raised portion on the lower surface of the lateral plate 502 is attached onto the surface, away from the first substrate 100, of the first die 300B with a smaller height, and the flat portion on the lower surface of the lateral plate 502 is attached onto the surface, away from the first substrate 100, of the first die 300A with a larger height; and referring to the right part in FIG. 14, the recessed portion on the lower surface of the lateral plate 502 is attached onto the surface, away from the first substrate 100, of the first die 300A with a larger height, and the flat portion of the lateral plate 502 is attached onto the surface, away from the first substrate 100, of the first die 300B with a smaller height. In this way, the heat produced by the flip-mounted plurality of first dies 300 with different heights is efficiently and quickly dissipated.

In some embodiments, referring to FIG. 13, when part of the first dies 300 (for example, 300A and 300B) are flip-mounted onto the first substrate 100 along cutting line BB1, the lateral plate 502 is attached onto the surface, away from the first substrate 100, of each of the first dies (300A and 300B). In some other embodiments, referring to FIG. 15, when part of the first dies 300 (for example, 300A and 300C) are flip-mounted onto the first substrate 100 along cutting line AA1, the lateral plate 502 is still mounted onto the surface, away from the first substrate 100, of each of the first dies (300A and 300C). In this way, the heat is efficiently and quickly dissipated for the plurality of first dies 300 that are flip-mounted along different directions.

In some embodiments, the surface, attached onto the first die 300, of the lateral plate 502 is a rough surface, such that a contact area between the lateral plate 502 and the first die 300, and the heat produced by the first die 300 is quickly absorbed.

In some embodiments, the bottom portions of the two vertical plates 501 of the heat conductive plate 500 are attached onto the surface of the first substrate 100 by an adhesive (not illustrated in the drawings), and the lateral plate 502 is attached onto the surface, away from the first substrate 100, of the first die 300 by a thermal conductive adhesive 503, such that transfer of the heat is not affected while the heat conductive plate 500 is better secured.

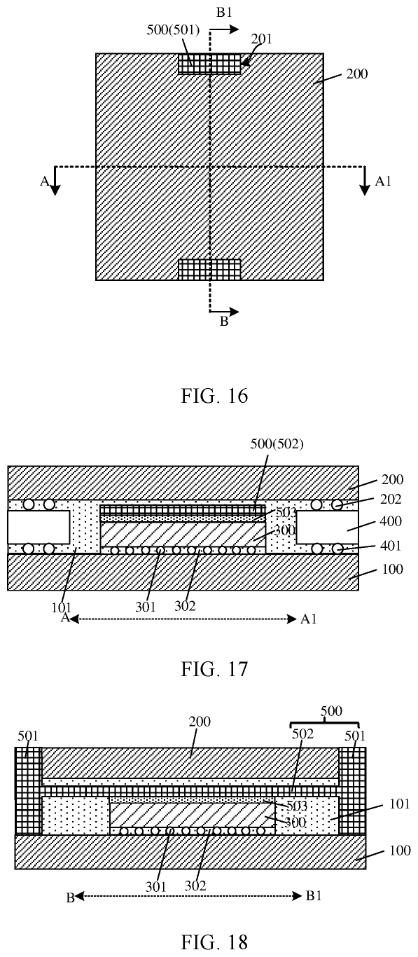

Referring to FIG. 16 to FIG. 18, FIG. 17 and FIG. 18 are schematic structural sectional views of FIG. 16 taken along cutting line AA1 and cutting line BB1. The second substrate 200 is mounted over the first substrate 100, and top portions of the two vertical plates 501 of the heat conductive plate 500 are respectively embedded into the two openings 201. A molding layer 101 is filled up in a space between the first substrate 100 and the second substrate 200, and the molding layer 101 wraps the first die 300 and the lateral plate 502.

In some embodiments, when the second substrate 200 is mounted over the first substrate 100, the first bumps 202 on the lower surface of the second substrate 200 are soldered onto an upper surface of the interposer structure 400. When the interposer structure 400 is an interposer plate, the first bumps 202 are electrically connected to the third wiring in the interposer plate. In some other embodiments, when the interposer structure 400 is a columnar conductive structure, the first bumps 202 are directly soldered onto an upper surface of the columnar conductive structure.

In some embodiments, when the second substrate 200 is mounted over the first substrate 100, the lower surface of the second substrate 200, the lower surface of the second substrate 200 is not in contact with the lateral plate 502 of the heat conductive plate 500.

In some embodiments, when the second substrate 200 is mounted over the first substrate 100, the top portions of the two vertical plates 501 of the heat conductive plate 500 are respectively embedded into the two openings 201. In this way, after the heat sink is mounted, the heat in the heat conductive plate 500 is more easily transferred upwards from the vertical plates 501 to the heat sink, and the second substrate 200 does not block transfer of the heat.

The molding layer 101 is formed by an injection molding process or a rotational molding process. In some embodiments, the molding layer 101 may be made of epoxy resin, polyimide resin, benzocyclobutene resin, or polybenzoxazole resin. In some other embodiments, the molding layer 101 may also be made of polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol.

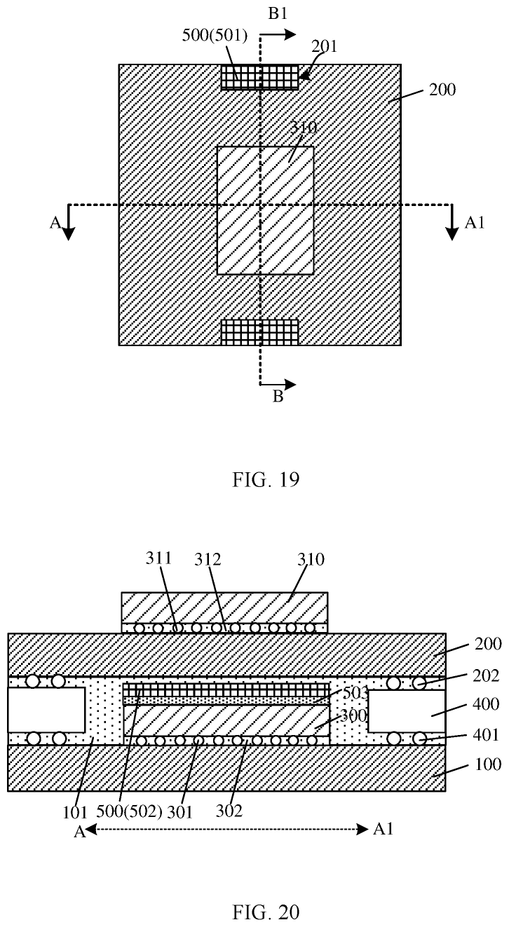

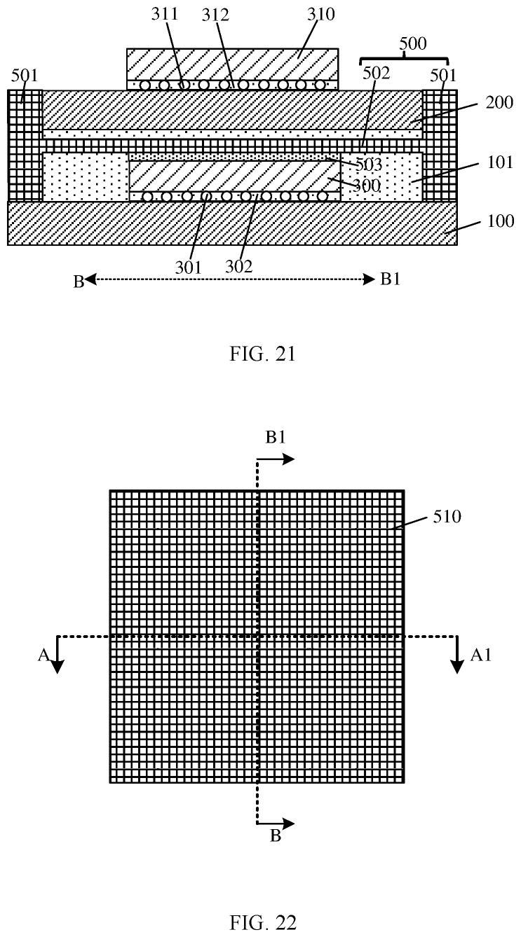

Referring to FIG. 19 to FIG. 21, FIG. 20 and FIG. 21 are respectively schematic structural sectional views of FIG. 19 taken along cutting line AA1 and cutting line BB1, wherein a second die 310 is provided. The second die 310 is flip-mounted onto a surface, away from the molding layer 101, of the second substrate 200 (or an upper surface of the second substrate).

The second die 310 includes a back surface and an active surface opposite to the back surface. A plurality of fourth bumps 311 are arranged on the active surface, and the plurality of fourth bumps 311 are connected to an integrated circuit formed in the second die 310. In this embodiment, the active surface of the second die 310 is flip-mounted onto the second substrate 200 (or the upper surface of the second substrate 200), the fourth bumps 311 on the active surface of the second die 310 are soldered to part of the second electrical connection points on the second substrate 200.

The second die 310 is a die having a specific function. In a specific embodiment, the second die 310 includes, but is not limited to, a sensor die, a power source die, a signal processing die, a logic control die, a storage die, or a radio frequency die. In some embodiments, the second die 310 has a different function from the first die 300.

In some embodiments, the fourth bumps 311 may be solder balls. In some other embodiments, the fourth bumps 311 may include metal columns or solder balls on top surfaces of the metal columns.

In some embodiments, after the second die 310 is flip-mounted onto the first substrate 200, a second underfill layer 312 is formed between the active surface of the second die 310 and the second substrate 200. The second underfill layer 312 is made of resin.

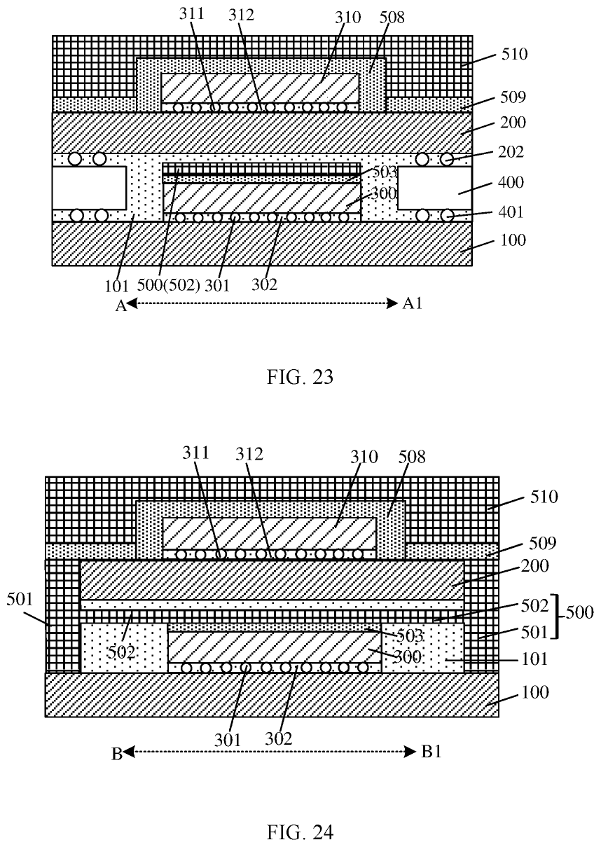

Referring to FIG. 22 to FIG. 24, FIG. 23 and FIG. 24 are respectively schematic structural sectional views of FIG. 22 taken along cutting line AA1 and cutting line BB1, wherein a heat sink 510 is provided. The heat sink 510 is mounted onto the surface, away from the molding layer 101, of the second substrate 200 (or the upper surface of the second substrate), and the heat sink 510 encircles an outer surface of the second die 310 (the outer surface includes a side surface of the second die 310 and a surface, i.e., a back surface, thereof away from the second substrate 200).

A recess matching the shape of the outer surface of the second die 310 is defined in the heat sink 510, the heat sink 510 is mounted onto the surface, away from the molding layer 101, of the second substrate 200, and the recess corresponds to the outer surface of the second die 310.

In some embodiments, the heat sink 510 is mounted onto the surface, away from the molding layer 101, of the second substrate 200, the heat sink 510 is attached onto the second die 310 by a thermal conductive adhesive 508, and the heat sink 510 is adhered onto the second substrate 200 by the thermal conductive adhesive and/or an adhesive 509.

In some embodiments, part of the heat sink 510 covers the openings in the second substrate 200, and the heat sink 510 covering the openings in the second substrate 200 is attached by a thermal conductive adhesive.

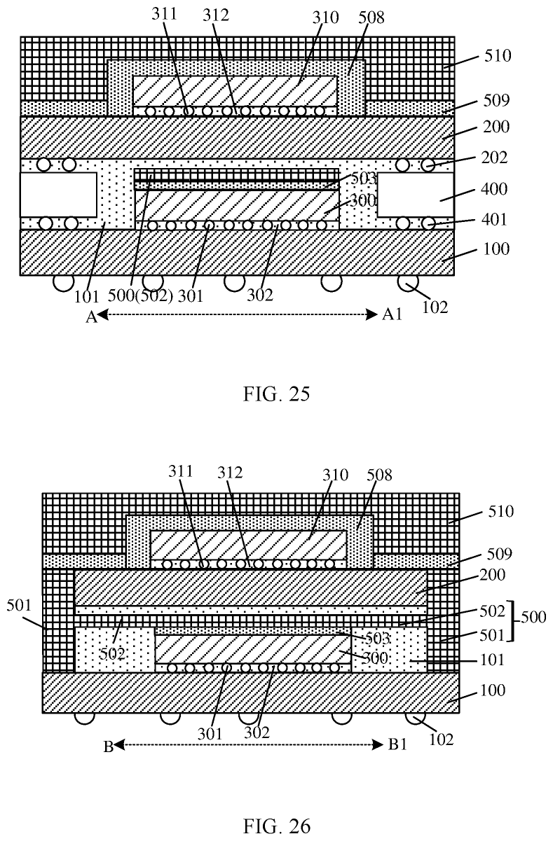

In some embodiments, referring to FIG. 25 and FIG. 26, a plurality of external bumps 102 are formed on the lower surface of the first substrate 100.

The external bumps 102 may be solder balls or solder bumps. The external bumps 102 may also include metal columns or solder balls on top surfaces of the metal columns.

Embodiments of the present disclosure provide a three-dimensional package structure. Referring to FIG. 22 to FIG. 24, the three-dimensional package structure includes:

at least one layer of first package, a second substrate 200, a second die 310, and a heat sink 510, wherein two openings running through the second substrate 200 are defined in the second substrate 200.

The at least one layer of first package includes a first substrate 100, at least one first die 300, a heat conductive plate 500, and a molding layer 101, wherein the heat conductive plate 500 includes two vertical plates 501 and a lateral plate 502 secured to middle positions of the two vertical plates 501, and the first die 300 is flip-mounted onto a surface (an upper surface) of the first substrate 100; the heat conductive plate 500 is mounted onto the first substrate 100, such that the bottom portions of the two vertical plates 501 of the heat conductive plate 500 are attached onto the surface (the upper surface) of the first substrate and the lateral plate 502 is attached onto a surface, away from the first substrate 100, of the first die 300; and the molding layer 101 wraps the first die 300 and the lateral plate 502, and exposes top surfaces of the two vertical plates 501.

The second substrate 200 is positioned on the first package, and the top portions of the two vertical plates 501 of the heat conductive plate 500 are respectively embedded into the two openings.

The second die 310 is positioned on a surface, away from the molding layer 101, of the second substrate 200.

The heat sink 510 is positioned on the surface, away from the molding layer 101, of the second substrate 200, and the heat sink 510 encircles an outer surface (a side surface of the second die 310, and a surface, away from the second substrate 200, of the second die 310) of the second die 310.

In some embodiments, the three-dimensional package structure further includes: an interposer structure 400, wherein the interposer structure 400 is positioned between the first substrate 100 and the second substrate 200 and positioned on two sides of the lateral plate 502 of the heat conductive plate 500, and the interposer structure 400 is configured to be electrically connected to the first substrate 100 and the second substrate 200.

In some embodiments, a first wiring is arranged in the first substrate 100, and a second wiring is arranged in the second substrate 200, wherein the first die 300 is electrically connected to the first wiring, the second die 310 is electrically connected to the second wiring, the interposer structure 400 is electrically connected to the first wiring and the second wiring, and the interposer structure 400 includes an interposer plate or a columnar conductive structure.

In some embodiments, when a plurality of first dies 300 are arranged, the plurality of first dies 300 are dies having the same function or different functions and are flip-mounted onto the first substrate 100, the bottom portions of the two vertical plates 501 of the heat conductive plate 500 are attached onto the surface of the first substrate 100 outside the plurality of first dies 300, and the lateral plate 502 is attached onto the surface, away from the first substrate 100, of each of the plurality of first dies 300 (referring to FIG. 13).

In some embodiments, heights of the plurality of first dies 300 flip-mounted onto the first substrate 100 are equal or different; and when the heights of the plurality of first dies 300 flip-mounted onto the first substrate 100 are equal, the lateral plate 502 of the heat conductive plate 500 is a flat plate (referring to FIG. 13).

In some embodiments, a plurality of first dies 300 (for example, 300A and 300B) are flip-mounted onto the first substrate 100, and when heights of the plurality of first dies (300A and 300B) flip-mounted onto the first substrate 100 are different (for example, the height of the first die 300A on the left is greater than the height of the first die 300B on the right in the left part or right part in FIG. 14), an upper surface of the lateral plate 502 of the heat conductive plate 500 is a flat surface, and a raised portion (referring to the left part in FIG. 14) or a recessed portion (referring to the right part in FIG. 14) is formed on a lower surface of the lateral plate 502. The raised portion may have different heights depending on height differences of the first dies, and the recessed portion may have different heights depending on height difference. Description is given using the case where the two first dies (300A and 300B) the flip-mounted have different heights as an example, upon flip-mounting, the height of the first die 300A is greater than the height of the first die 300B, and correspondingly a raised portion (referring to the left part in FIG. 14) or a recessed portion (referring to the right part in FIG. 14) is formed on the lower surface of the lateral plate 502. During attaching of the lateral plate 502 in two different structures, referring to the left part in FIG. 14, the raised portion on the lower surface of the lateral plate 502 is attached onto the surface, away from the first substrate 100, of the first die 300B with a smaller height, and the flat portion on the lower surface of the lateral plate 502 is attached onto the surface, away from the first substrate 100, of the first die 300A with a larger height; and referring to the right part in FIG. 14, the recessed portion on the lower surface of the lateral plate 502 is attached onto the surface, away from the first substrate 100, of the first die 300A with a larger height, and the flat portion of the lateral plate 502 is attached onto the surface, away from the first substrate 100, of the first die 300B with a smaller height.

In some embodiments, the surface, attached onto the first die 300, of the lateral plate 502 is a rough surface.

In some embodiments, the bottom portions of the two vertical plates 501 of the heat conductive plate 500 are attached onto the surface of the first substrate 100 by an adhesive, the lateral plate 502 is attached onto the surface, away from the first substrate 100, of the first die 300 by a thermal conductive adhesive, the heat sink 510 is attached onto the second die 310 by a thermal conductive adhesive 508, and the heat sink 510 is adhered onto the second substrate 200 by a thermal conductive adhesive and/or an adhesive.

In some embodiments, part of the heat sink 510 covers the openings in the second substrate 200, and the heat sink 510 covering the openings in the second substrate 200 is attached by a thermal conductive adhesive.

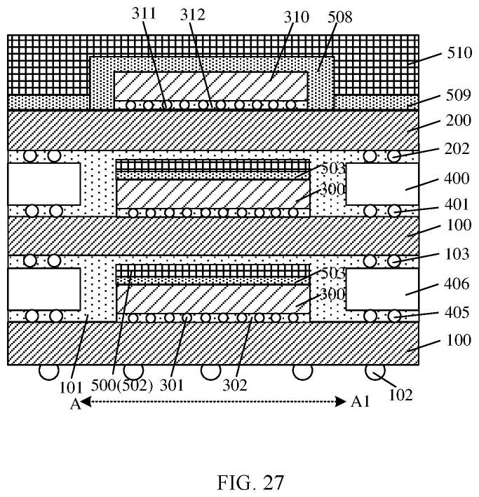

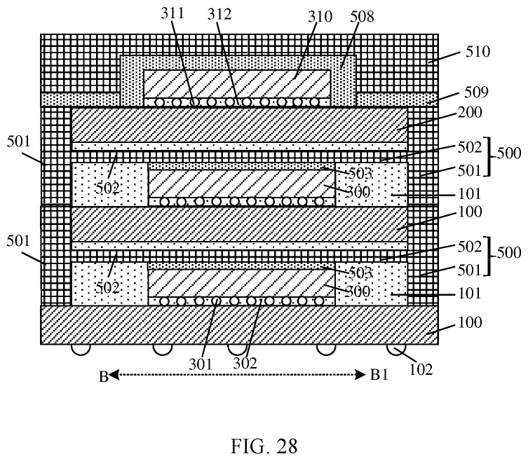

In some embodiments, referring to FIG. 27 and FIG. 28, when a plurality of layers of the first package are arranged, the plurality of layers of the first package are stacked along a vertical direction (the vertical direction is a direction perpendicular to the upper surface of the first substrate), and the second substrate 200 is mounted over the first substrate 100 in the first package in an uppermost layer; and the first substrates 100 in upper and lower layers are electrically connected by a second interposer structure 406. Upper and lower surfaces of the second interposer structure 406 are respectively connected to surfaces of the upper and lower substrates in the upper and lower layers by soldering bumps 103 and soldering bumps 405.

It should be noted that in the embodiments, parts of the three-dimensional package structure that are the same as or similar to those of the method for forming the three-dimensional package structure are not described herein any further. For details, reference may be made to definition and description of the corresponding parts in the embodiments illustrating the method for forming the three-dimensional package structure.

Although the present disclosure has been disclosed above with reference to preferred embodiments, these embodiments are not intended to limit the present disclosure but illustrate the present disclosure. Without departing from the spirit and scope of the present disclosure, any person skilled in the art may make possible variations and modifications to the technical solutions based on the method and technical content disclosed herein in this literature. Therefore, any content without departing from the technical solutions of the present disclosure and any simple variation, equivalent replacement and modification made based on the technical essence of the present disclosure shall fall within the protection scope defined by the technical solutions of the present disclosure.

What is claimed is:

1. A method for forming a three-dimensional package structure, comprising:
providing a first substrate, a second substrate, at least one first die, a second die, a heat conductive plate, and a heat sink, wherein the heat conductive plate comprises two vertical plates and a lateral plate secured to middle positions of the two vertical plates, and two openings running through the second substrate are defined in the second substrate;
flip-mounting the at least one first die onto the first substrate;
mounting the heat conductive plate onto the first substrate, such that bottom portions of the two vertical plates of the heat conductive plate are attached onto a surface of the first substrate and the lateral plate is attached onto a surface, away from the first substrate, of the at least one first die;
mounting the second substrate over the first substrate, such that top portions of the two vertical plates of the heat conductive plate are respectively embedded into the two openings;
filling up a space between the first substrate and the second substrate with a molding layer, wherein the molding layer wraps the at least one first die and the lateral plate;
flip-mounting the second die onto a surface, away from the molding layer, of the second substrate; and
mounting the heat sink onto the surface, away from the molding layer, of the second substrate, such that the heat sink encircles an outer surface of the second die.

2. The method according to claim 1, further comprising: providing an interposer structure, wherein the interposer structure is positioned between the first substrate and the second substrate and positioned on two sides of the lateral plate of the heat conductive plate, and the interposer structure is configured to be electrically connected to the first substrate and the second substrate.

3. The method according to claim 2, wherein a first wiring is arranged in the first substrate, and a second wiring is arranged in the second substrate, wherein the at least one first die is electrically connected to the first wiring, the second die is electrically connected to the second wiring, the interposer structure is electrically connected to the first wiring and the second wiring, and the interposer structure comprises an interposer plate or a columnar conductive structure.

4. The method according to claim 1, wherein a plurality of first dies are arranged, the plurality of first dies have the same function or different functions and are flip-mounted onto the first substrate, the bottom portions of the two vertical plates of the heat conductive plate are attached onto a surface of the first substrate outside the plurality of first dies, and the lateral plate is attached onto the surface, away from the first substrate, of each of the plurality of first dies.

5. The method according to claim 4, wherein heights of the plurality of first dies flip-mounted onto the first substrate are equal or different.

6. The method according to claim 5, wherein heights of the plurality of first dies flip-mounted onto the first substrate are equal, the lateral plate of the heat conductive plate is a flat plate.

7. The method according to claim 5, wherein the heights of the plurality of first dies flip-mounted onto the first substrate are different, an upper surface of the lateral plate of the heat conductive plate is a flat surface, and a raised portion or a recessed portion is defined in a lower surface of the lateral plate, wherein the recessed portion in the lower surface of the lateral plate is attached onto a surface, away from the first substrate, of a first die with a larger height, or the raised portion in the lower surface of the lateral plate is attached onto a surface, away from the first substrate, of a first die with a smaller height.

8. The method according to claim 1, wherein the bottom portions of the two vertical plates of the heat conductive plate are attached onto the surface of the first substrate by an adhesive, the lateral plate is attached onto the surface, away from the first substrate, of the at least one first die by a thermal conductive adhesive, the heat sink is attached onto the second die by a thermal conductive adhesive, and the heat sink is attached to the second substrate by at least one of a thermal conductive adhesive and an adhesive.

9. The method according to claim 8, wherein part of the heat sink covers the two openings in the second substrate, and the heat sink covering the two openings in the second substrate is attached by a thermal conductive adhesive.

10. A three-dimensional package structure, comprising:
at least one layer of first package, a second substrate, a second die, and a heat sink, wherein two openings running through the second substrate are defined in the second substrate; wherein
the at least one layer of first package comprises a first substrate, at least one first die, a heat conductive plate, and a molding layer, wherein the heat conductive plate comprises two vertical plates and a lateral plate secured to middle positions of the two vertical plates, and the at least one first die is flip-mounted onto a surface of the first substrate; the heat conductive plate is mounted onto the surface of the first substrate, such that bottom portions of the two vertical plates of the heat conductive plate are attached onto the surface of the first substrate and the lateral plate is attached onto a surface, away from the first substrate, of the at least one first die; and the molding layer wraps the at least one first die and the lateral plate, and exposes top surfaces of the two vertical plates;
the second substrate is positioned on the first package, and top portions of the two vertical plates of the heat conductive plate are respectively embedded into the two openings;
the second die is positioned on a surface, away from the molding layer, of the second substrate; and
the heat sink is positioned on the surface, away from the molding layer, of the second substrate, and the heat sink encircles an outer surface of the second die.

11. The three-dimensional package structure according to claim 10, further comprising: an interposer structure, wherein the interposer structure is positioned between the first substrate and the second substrate and positioned on two sides of the lateral plate of the heat conductive plate, and the interposer structure is configured to be electrically connected to the first substrate and the second substrate.

12. The three-dimensional package structure according to claim 11, wherein a first wiring is arranged in the first substrate, and a second wiring is arranged in the second substrate, wherein the at least one first die is electrically connected to the first wiring, the second die is electrically connected to the second wiring, the interposer structure is electrically connected to the first wiring and the second wiring, and the interposer structure comprises an interposer plate or a columnar conductive structure.

13. The three-dimensional package structure according to claim 10, wherein a plurality of first dies are arranged, the plurality of first dies have the same function or different functions and are flip-mounted onto the first substrate, the bottom portions of the two vertical plates of the heat conductive plate are attached onto a surface of the first substrate outside the plurality of first dies, and the lateral plate is attached onto the surface, away from the first substrate, of each of the plurality of first dies.

14. The three-dimensional package structure according to claim 13, wherein heights of the plurality of first dies flip-mounted onto the first substrate are equal or different.

15. The three-dimensional package structure according to claim 14, wherein heights of the plurality of first dies flip-mounted onto the first substrate are equal, the lateral plate of the heat conductive plate is a flat plate.

16. The three-dimensional package structure according to claim 14, wherein the heights of the plurality of first dies flip-mounted onto the first substrate are different, an upper surface of the lateral plate of the heat conductive plate is a flat surface, and a raised portion or a recessed portion is defined in a lower surface of the lateral plate, wherein the recessed portion in the lower surface of the lateral plate is attached onto a surface, away from the first substrate, of a first die with a larger height, or the raised portion in the lower surface of the lateral plate is attached onto a surface, away from the first substrate, of a first die with a smaller height.

17. The method according to claim 11, wherein the bottom portions of the two vertical plates of the heat conductive plate are attached onto the surface of the first substrate by an adhesive, the lateral plate is attached onto the surface, away from the first substrate, of the at least one first die by a thermal conductive adhesive, the heat sink is attached onto the second die by a thermal conductive adhesive, and the heat sink is attached onto the second substrate by at least one of a thermal conductive adhesive and an adhesive.

18. The three-dimensional package structure according to claim 17, wherein part of the heat sink covers the two openings in the second substrate, and the heat sink covering the two openings in the second substrate is attached by a thermal conductive adhesive.

19. The three-dimensional package structure according to claim 10, wherein a plurality of layers of first package are arranged, the plurality of layers of first package are stacked along a vertical direction, and the second substrate is mounted over a first substrate in an uppermost layer of first package; and first substrates in upper and lower layers of first package are electrically connected by a second interposer structure.
